(19) United States
(12) Patent Application Publication
(10) Pub. No.: US 2025/0293675 A1
(43) Pub. Date: Sep. 18, 2025

(54) Signal output apparatus having programmable slew rate

(71) Applicant: REALTEK SEMICONDUCTOR CORPORATION, HSINCHU (TW)

(72) Inventor: HENG-CHIA HSU, Hsinchu (TW)

(21) Appl. No.: 19/055,862

(22) Filed: Feb. 18, 2025

(30) Foreign Application Priority Data
Mar. 12, 2024 (TW) 113109068

(51) Int. Cl. H03K 5/133; H03K 5/06; H03K 19/0185

(52) U.S. Cl. CPC H03K 5/133; H03K 5/06; H03K 19/018585

(57) ABSTRACT

The present disclosure discloses a signal output apparatus having programmable slew rate that includes output units. The output units are coupled in parallel between an input terminal and an output terminal and each corresponds to a variable signal delay amount. Each of the output units includes a delay path and an output circuit. The delay path provides the variable signal delay amount to receive and delay an input signal from the input terminal to generate a delayed signal. The output circuit receives the delayed signal and generates an output signal to the output terminal. The output terminal outputs a total output signal according to the output signals generated by the output circuits of all the output units, in which a slew rate of the total output signal is determined by a combination of the variable signal delay amounts of all the output units.

### BACKGROUND OF THE INVENTION

### 1. Field of the Invention

The present disclosure relates to a signal output apparatus having a programmable slew rate.

### 2. Description of Related Art

In electronic apparatuses, the transmission of the signals is performed by a signal output circuit such that a driver circuit in the signal output circuit is used to drive the signal to be outputted.

When the signal outputted by the driver circuit transits, the rise time of the signal transiting from a low state to a high state and a fall time of the signal transiting from the high state to the low state need to match the requirements such that the slew rate is within a reasonable range. For example, when the driver circuit operates under a high speed, a shorter rise time and a shorter fall time can be tolerated such that a higher slew rate is tolerated. However, when the driver circuit operates under a low speed, the rise time and the fall time should be larger than a predetermined value, in which a lower slew rate is tolerated. If the driver circuit does not have an elastic slew rate adjusting mechanism, the requirements of the slew rate under different speeds cannot be satisfied.

### SUMMARY OF THE INVENTION

In consideration of the problem of the prior art, an object of the present disclosure is to provide a signal output apparatus having a programmable slew rate.

The present invention discloses a signal output apparatus having programmable slew rate that includes a plurality of output units electrically coupled in parallel between an input terminal and an output terminal each corresponding to a variable signal delay amount, each of the output units includes a delay path and an output circuit. The delay path is configured to provide the variable signal delay amount and to receive and delay an input signal from the input terminal to generate a delayed signal. The output circuit receives the delayed signal and generates an output signal to an output terminal. The output terminal outputs a total output signal according to the output signals generated from the output circuits of the output units, and a slew rate of the total output signal is determined by a combination of the variable signal delay amounts of all the output units.

These and other objectives of the present disclosure will no doubt become obvious to those of ordinary skill in the art after reading the following detailed description of the preferred embodiments that are illustrated in the various figures and drawings.

### BRIEF DESCRIPTION OF THE DRAWINGS

FIG. 1 illustrates a block diagram of a signal output apparatus having a programmable slew rate according to an embodiment of the present invention.

FIG. 2A and FIG. 2B respectively illustrate a block diagram of one output unit according to an embodiment of the present invention.

FIG. 3 illustrates a waveform diagram of the total the output signal outputted by the output terminal according to an embodiment of the present invention.

FIG. 4 illustrates a block diagram of one output unit according to another embodiment of the present invention.

FIG. 5 illustrates a block diagram of one output unit according to yet another embodiment of the present invention.

### DETAILED DESCRIPTION OF THE PREFERRED EMBODIMENTS

An aspect of the present invention is to provide a signal output apparatus having a programmable slew rate to dispose output units each corresponding to a variable signal delay amount so as to determine the slew rate of the total output signal according to the combination of the variable signal delay amounts of the different output units to accomplish a programmable slew rate that can be adjusted elastically.

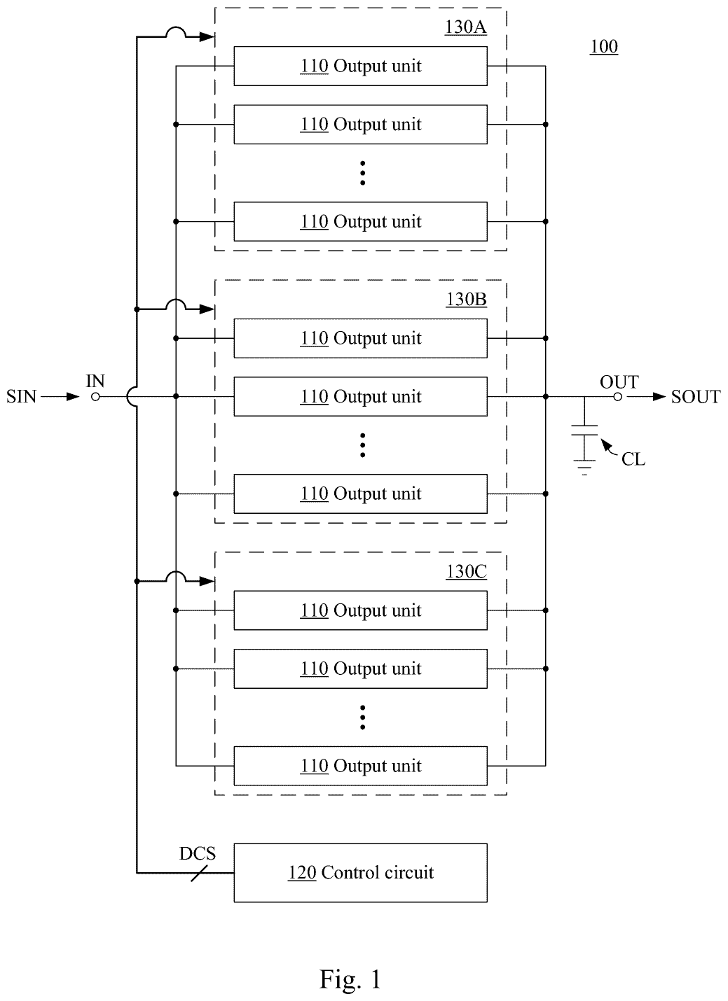

Reference is now made to FIG. 1. FIG. 1 illustrates a block diagram of a signal output apparatus 100 having a programmable slew rate according to an embodiment of the present invention.

In an embodiment, the signal output apparatus 100 can be used in a signal transmission interface of such as, but not limited to High Definition Multimedia Interface (HDMI), DisplayPort (DP) or Universal Serial Bus (USB) and is configured to be a driver circuit of a signal output circuit (TX) to output signals. However, the present invention is not limited thereto.

The signal output apparatus 100 includes a plurality of output units 110 and a control circuit 120.

The output units 110 are electrically coupled in parallel between an input terminal IN and an output terminal OUT each corresponding to a variable signal delay amount.

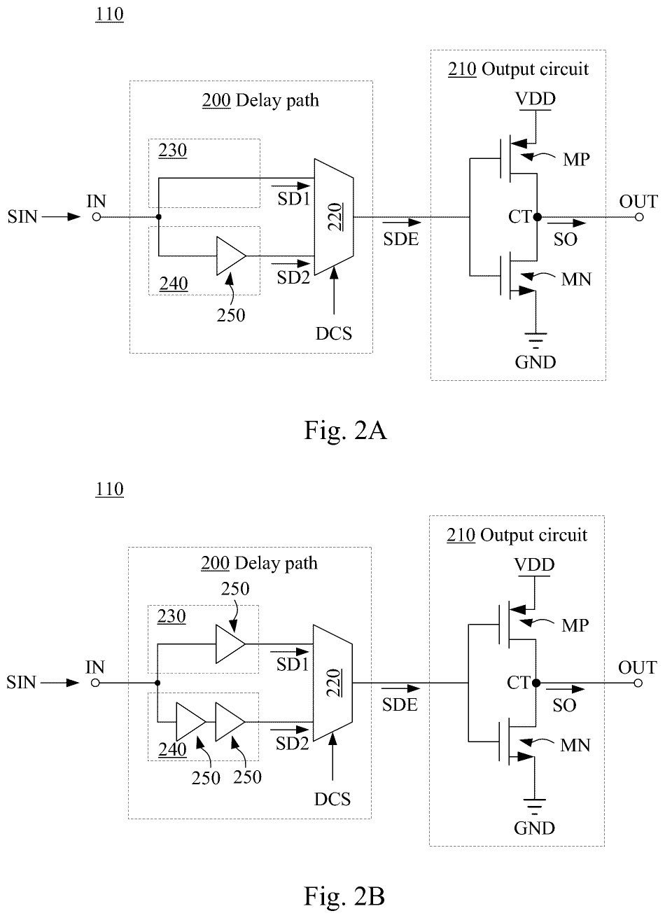

Reference is now made to FIG. 2A and FIG. 2B at the same time. FIG. 2A and FIG. 2B respectively illustrate a block diagram of one output unit 110 according to an embodiment of the present invention. The output unit 110 includes a delay path 200 and an output circuit 210.

The delay path 200 is configured to provide the variable signal delay amount and to receive and delay an input signal SIN from the input terminal IN to generate a delayed signal SDE.

In the present embodiment, the delay path 200 includes a multiplexer 220, a first delay sub-path 230 and a second delay sub-path 240.

The first delay sub-path 230 is electrically coupled between the input terminal IN and the multiplexer 220 and has a first delay element number of M to delay the input signal SIN to generate a first delayed signal SD1, wherein M is an integer larger than or equaling to 0.

The second delay sub-path 240 is electrically coupled between the input terminal IN and the multiplexer 220 and has second delay element number of N that is different from the first delay element number of M to delay the input signal SIN to generate a second delayed signal SD2, wherein N is an integer larger than or equaling to 0.

In the embodiment in FIG. 2A, the condition that M=0 and N=1 is used as an example. More specifically, since the first delay element number M is 0, the first delay sub-path 230 does not include any delay element. The first delayed signal SD1 is generated by directly outputting the input signal SIN without delay. Since the second delay element number N is 1, the second delay sub-path 240 includes one delay element 250. When one delay element 250 causes one unit of delay amount, the second delayed signal SD2 is equivalent to be generated by delaying the input signal SIN for one unit of delay amount.

In the embodiment of FIG. 2B, the condition that M=1 and N=2 is used as an example. More specifically, since the first delay element number M is 1, the first delay sub-path 230 includes one delay element 250. The first delayed signal SD1 is equivalent to be generated by delaying the input signal SIN for one unit of delay amount. Since the second delay element number N is 2, the second delay sub-path 240 includes two delay elements 250. The second delayed signal SD2 is equivalent to be generated by delaying the input signal SIN for two units of delay amount.

It is appreciated that the values of the first delay element number M and the second delay element number N described above are merely an example. In other embodiments, the first delay element number M and the second delay element number N can be configured to be other values. Further, the first delay sub-path 230 and the second delay sub-path 240 in different output units 110 can be configured to include different combinations of the first delay element number M and the second delay element number N (e.g., some of the output units 110 have the configuration in FIG. 2A and some of the output units 110 have the configuration in FIG. 2B). The present invention is not limited thereto.

The multiplexer 220 is configured to select one of the first delayed signal SD1 and the second delayed signal SD2 to be outputted as the delayed signal SDE. As a result, the selection of the multiplexer 220 determines the variable signal delay amount of the output unit 110. In an embodiment, the multiplexer 220 performs the selection based on the control of a delay control signal DCS.

For example, in the embodiment of FIG. 2A, when the multiplexer 220 selects the first delay sub-path 230, the variable signal delay amount of the output unit 110 is 0. When the multiplexer 220 selects the second delay sub-path 240, the variable signal delay amount of the output unit 110 is one unit of delay amount.

In the embodiment of FIG. 2B, when the multiplexer 220 selects the first delay sub-path 230, the variable signal delay amount of the output units 110 variable signal delay amount is one unit of delay amount. When the multiplexer 220 selects the second delay sub-path 240, the variable signal delay amount of the output unit 110 is two units of delay amount.

The output circuit 210 receives the delayed signal SDE and generates an output signal SO to the output terminal OUT. In an embodiment, the output circuit 210 is flip-flop and includes a P-type transistor MP and an N-type transistor MN.

The P-type transistor MP is electrically coupled between a power supply terminal VDD and a connection terminal CT. More specifically, the source of the P-type transistor MP is electrically coupled to the power supply terminal VDD and the drain of the P-type transistor MP is electrically coupled to the connection terminal CT. The connection terminal CT is electrically coupled to the output terminal OUT.

The N-type transistor MN is electrically coupled between the connection terminal CT and a ground terminal GND. More specifically, the drain of the N-type transistor MN is electrically coupled to the connection terminal CT and the source of the N-type transistor MN is electrically coupled to the ground terminal GND.

The P-type transistor MP and the N-type transistor MN are controlled by the delayed signal SDE and generates the output signal SO at the connection terminal CT. More specifically, the gates of the P-type transistor MP and the N-type transistor MN receive the delayed signal SDE such that the P-type transistor MP and the N-type transistor MN turn on or turn off according to the state of the delayed signal SDE to generate the output signal SO at the connection terminal CT.

For example, when the input signal SIN received by the delay path 200 is at the high state, the delayed signal SDE is at the high state as well such that the P-type transistor MP turns off and the N-type transistor MN turns on. The turn-on N-type transistor MN has a corresponding conduction resistance (Ron) and discharges the connection terminal CT such that the output signal SO is at the low state.

When the input signal SIN received by the delay path 200 is at the low state, the delayed signal SDE is at the low state as well such that the P-type transistor MP turns on and the N-type transistor MN turns off. The turn-on P-type transistor MP has a corresponding conduction resistance to charge the connection terminal CT such that the output signal SO is at the high state.

It is appreciated that the configuration of the output circuit 210 described above is merely an example. In other embodiments, the output circuit 210 can be implemented by circuits of the types of other that the flip-flop circuit. The present invention is not limited thereto.

The output terminal OUT in FIG. 1 outputs a total the output signal SOUT according to the output signal SO generated from the output circuits 210 of all the output units 110. In an embodiment, a load capacitor CL is disposed at the output terminal OUT.

The slew rate of the total the output signal SOUT is determined by the combination of the variable signal delay amounts of the output units 110. The configuration of the variable signal delay amount and the relation between the variable signal delay amount and the slew rate are described in the following paragraphs.

In an embodiment, the control circuit 120 in FIG. 1 is configured to generate the delay control signal DCS to each of the output units 110 to control the multiplexer 220 in the delay path 200 of each of the output units 110 to perform selection. According to the configuration of the numbers of the delay elements in the first delay sub-path 230 and the second delay sub-path 240 and the selection of the delay sub-path performed by the delay control signal DCS, the output units 110 can be configured to have a specific combination of the variable signal delay amount to accomplish the required slew rate.

For example, based on the configuration of the numbers of the delay elements and the selection performed by the delay control signal DCS, the output units 110 are categorized into a plurality of output groups. The variable signal delay amount of each of the output units 110 in the output groups is the same and the variable signal delay amounts of the output units 110 in the different output groups are different.

In the embodiment of FIG. 1, the output units 110 are categorized into three output groups 130A, 130B and 130C. A possible configuration is described below.

Each of the output units 110 in the output group 130A is implemented by the configuration in FIG. 2A and the first delayed signal SD1 generated by the first delay sub-path 230 is selected by the multiplexer 220 to be outputted as the delayed signal SDE such that the output circuit 210 generates the output signal SO accordingly. Under such a condition, the variable signal delay amount that each of the output units 110 in the output group 130A corresponds to is 0.

Each of the output units 110 in the output group 130B is implemented by the configuration in FIG. 2A and the second delayed signal SD2 generated by the second delay sub-path 240 is selected by the multiplexer 220 to be outputted as the delayed signal SDE such that the output circuit 210 generates the output signal SO accordingly. Under such a condition, the variable signal delay amount that each of the output units 110 in the output group 130B corresponds to is one unit of delay amount.

Each of the output units 110 in the output group 130C is implemented by the configuration in FIG. 2B and the second delayed signal SD2 generated by the second delay sub-path 240 is selected by the multiplexer 220 to be outputted as the delayed signal SDE such that the output circuit 210 generates the output signal SO accordingly. Under such a condition, the variable signal delay amount that each of the output units 110 in the output group 130C corresponds to is two units of delay amount.

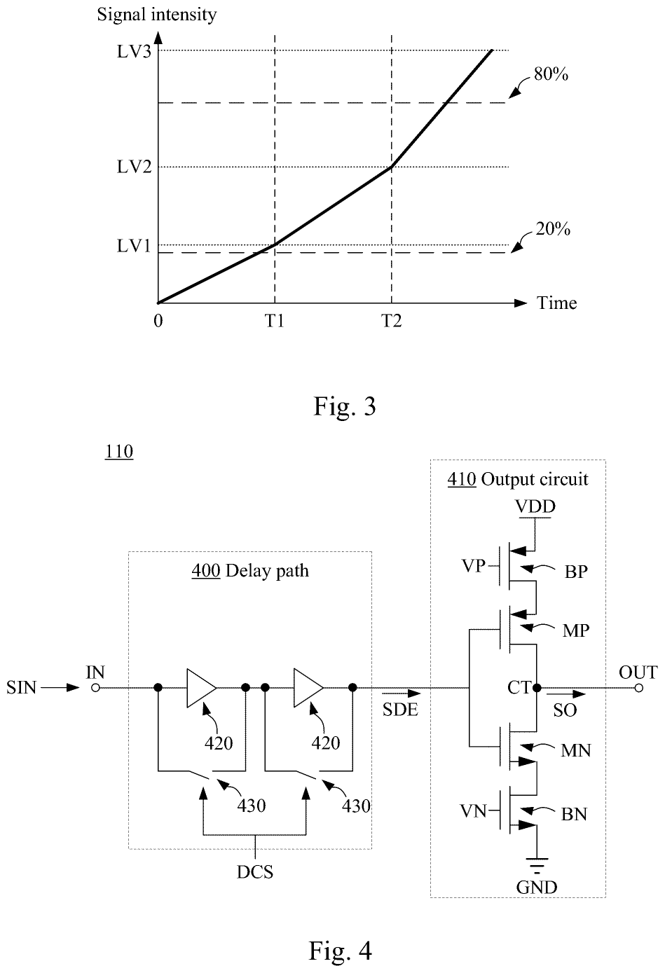

The condition that the number of the output units 110 included in each of the output groups 130A, 130B and 130C is the same and the total number of the output units 110 is K (each of the output groups includes K/3 output units) is used as an example to describe the process that the total the output signal SOUT transits from the low state to the high state in accompany with FIG. 3 in the following paragraphs.

Reference is now made to FIG. 3. FIG. 3 illustrates a waveform diagram of the total the output signal SOUT outputted by the output terminal OUT according to an embodiment of the present invention. In FIG. 3, the X-axis stands for the time and the Y-axis stands for the signal intensity.

In FIG. 3, the time begins at zero. The time spot T1 corresponds to the time length of one unit of delay amount and the time spot T2 corresponds to the time length of two units of delay amount.

In the present embodiment, the input signal SIN received by the output units 110 transits from the high state to the low state. The output signal SO generated by each of the output units 110 transits from the low state to the high state such that the total the output signal SOUT outputted by the output terminal OUT also transits from the low state to the high state.

Since the variable signal delay amount that each of the output units 110 in the output group 130A corresponds to is 0, each of the output units 110 in the output group 130A begins to generate the output signal SO from the time spot that is 0 (the signal processing time of the output circuit 210 is not taken into consideration). As a result, from the time spot 0 to the time spot T1, the total the output signal SOUT outputted by the output terminal OUT only includes the output signal SO generated by each of the output units 110 of the output group 130A such that the signal intensity increases from 0 to a first level LV1.

If a conductive resistance of the P-type transistor MP of the output circuit 210 in the output units 110 is R, the output units 110 in the output group 130A having the number of K/3 and coupled in parallel makes the equivalent resistance of the output units 110 of output group 130A become R/(K/3)=3R/K. When the capacitance of the load capacitor CL at the output terminal OUT is C, the equivalent RC time constant of the output units 110 from the time spot 0 to the time spot T1 is a product of the equivalent resistance 3R/K of the output units 110 and the capacitance of the load capacitor CL, which is (3R/K)×C=3RC/K.

Since the variable signal delay amount that each of the output units 110 of the output group 130B corresponds to is one unit of delay amount, each of the output units 110 of the output group 130B begins to generate the output signal SO from the time spot T1. As a result, from the time spot T1 to the time spot T2, the total the output signal SOUT outputted by the output terminal OUT simultaneously includes the output signal SO of each of the output units 110 in the output groups 130A and 130B such that the signal intensity increases from the first level LV1 to a second level LV2.

If a conductive resistance of the P-type transistor MP of the output circuit 210 in the output units 110 is R, the output units 110 in the output groups 130A and 130B having the number of 2K/3 and coupled in parallel makes the equivalent resistance of the output units 110 of output groups 130A and 130B become R/(2K/3)=3R/2K. When the capacitance of the load capacitor CL at the output terminal OUT is C, the equivalent RC time constant of the output units 110 from the time spot T1 to the time spot T2 is (3R/K)×C=3RC/2K. Under the condition that the equivalent RC time constant decreases, the rising speed of the intensity of the total the output signal SOUT from the time spot T1 to the time spot T2 is higher than the rising speed of the intensity of the total the output signal SOUT from the time spot 0 to the time spot T1.

Since the variable signal delay amount that each of the output units 110 of the output group 130C corresponds to is two units of delay amount, each of the output units 110 of the output group 130C begins to generate the output signal SO from the time spot T2. As a result, from the time spot T2, the total the output signal SOUT outputted by the output terminal OUT simultaneously includes the output signal SO of each of the output units 110 in the output groups 130A, 130B and 130C such that the signal intensity increases from the first level LV2 to a second level LV3.

If a conductive resistance of the P-type transistor MP of the output circuit 210 in the output units 110 is R, the output units 110 in the output groups 130A, 130B and 130C having the number of K and coupled in parallel makes the equivalent resistance of the output units 110 of output groups 130A, 130B and 130C become R/K. When the capacitance of the load capacitor CL at the output terminal OUT is C, the equivalent RC time constant of the output units 110 after the time spot T2 is R/K×C=RC/K. Under the condition that the equivalent RC time constant further decreases, the rising speed of the intensity of the total the output signal SOUT after the time spot T2 is higher than the rising speed of the intensity of the total the output signal SOUT from the time spot T1 to the time spot T2.

In an embodiment, the time that the signal intensity of the total the output signal SOUT increases from the 20% of a maximum value to the 80% of the maximum value can be defined as a rise time, in which the equivalent slope between the signal variation and the time is the slew rate. In an embodiment, the slew rate of the total the output signal SOUT is determined by the combination of the variable signal delay amounts of the output units 110.

More specifically, according the example in FIG. 3, different variable signal delay amounts are assigned to the output units 110 categorized into the different output groups. The time spots that the output circuits 210 of the output units 110 in different output groups perform signal transmission are different such that the equivalent resistance of the output units 110 relative to the output terminal OUT gradually increases along with the time. Such a configuration increases the rise time of the total the output signal SOUT such that the slew rate is not too high. As a result, the combination of the variable signal delay amounts determines the slew rate of the total the output signal SOUT.

For example, when the variable signal delay amount of at least part of the output units 110 have an even larger value, the rise time of the total the output signal SOUT increases more such that the slew rate further decreases. When the variable signal delay amount of at least part of the output units 110 have an even smaller value, the rise time of the total the output signal SOUT decreases more such that the slew rate further increases.

Further, in an embodiment, the linearity of the total the output signal SOUT can be determined by the number of the output groups and the number of the output units in each of the output groups.

More specifically, according to the example in FIG. 3, when the combination of the variable signal delay amounts includes more different values of the variable signal delay amounts, the number of the output groups increases such that the variation time of the equivalent resistance increases and the rise time increases along with more different time sections.

When the numbers of the output units of the output groups are different, the variations of the equivalent resistance that the output groups cause are different. The amount of the increasing of the rise time in different time sections are thus affected, in which the variation of the rise time of each of the time sections is related to the corresponding equivalent RC time constant.

As a result, under an appropriate configuration of the number of the output groups and the number of the output units included by the output groups, the linearity of the signal transmission of each of the output groups can be approximately the same to increase the linearity of the total slew rate.

It is appreciated that the embodiment in FIG. 3 uses the condition that the total the output signal SOUT transits from the low state to the high state as an example. However, the description made to FIG. 3 can be applied to the fall time that the total the output signal SOUT transits from the high state to the low state and the slew rate corresponding thereto. The only difference is that when the total the output signal SOUT transits from the high state to the low state, the equivalent resistance of the output units 110 is related to the conduction resistance of the N-type transistor MN in the output circuit 210 such that the equivalent RC time constant varies accordingly.

Reference is now made to FIG. 4. FIG. 4 illustrates a block diagram of one output unit 110 according to another embodiment of the present invention. The output unit 110 in FIG. 4 includes a delay path 400 and an output circuit 410.

In the present embodiment, the delay path 400 includes two delay elements 420 and two bypass elements 430. Each of the bypass elements 430 corresponds to one of the delay elements 420 and is configured to bypass the corresponding one of the delay elements 420 when being enabled and not bypass the corresponding one of the delay elements 420 when being disabled.

In an embodiment, the control circuit 120 in FIG. 1 is configured to generate the delay control signal DCS to each of the output units 110 to enable or disable the bypass element 430 in the delay path 400 of each of the output units 110. By using the delay control signal DCS to control the combination of the bypassed and the non-bypassed delay elements 420, the output units 110 have a specific combination of the variable signal delay amounts to accomplish the required slew rate.

Take the embodiment in FIG. 4 as an example, the delay control signal DCS may bypass all the delay elements 420 of a part of the output units 110, bypass one of the delay elements 420 in another part of the output units 110 and not bypass all the delay elements 420 of yet another output units 110 so as to categorize the output units 110 into three output groups 130A, 130B and 130C as illustrated in FIG. 1. The variable signal delay amounts with 0, 1 and 2 units of delay amount can be configured respectively. The output result of the total the output signal SOUT illustrated in FIG. 3 can be accomplished according to the configuration of the output groups described above.

On the other hand, the output circuit 410 in the present embodiment also includes the P-type transistor MP and the N-type transistor MN and has the connection same as the P-type transistor MP and the N-type transistor MN in the output circuit 210 in FIG. 2. However, the output circuit 410 may further include a first biased load transistor BP and a second biased load transistor BN.

The first biased load transistor BP is electrically coupled in series with the P-type transistor MP between the power supply terminal VDD and the connection terminal CT and is controlled by a bias voltage VP to always turn on and operate as a load. The second biased load transistor BN electrically coupled in series with the N-type transistor MN between the connection terminal CT and the ground terminal GND and is controlled by a bias voltage VN to always turn on and operate as a load.

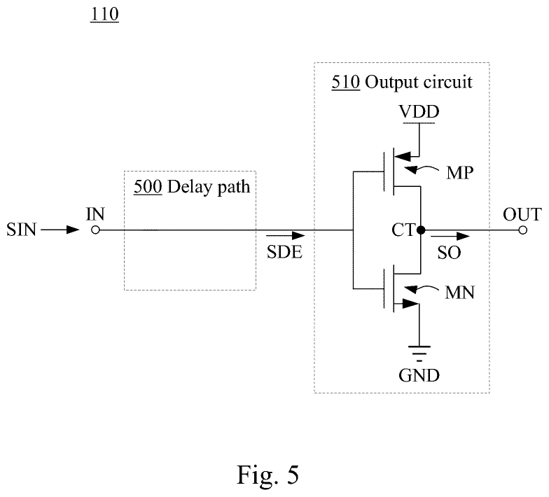

Reference is now made to FIG. 5. FIG. 5 illustrates a block diagram of one output unit 110 according to yet another embodiment of the present invention. The output unit 110 in FIG. 5 includes a delay path 500 and an output circuit 510.

In the present embodiment, the delay path 500 does not include any delay element. The output circuit 510 may include the configuration of the output circuit 210 in FIG. 2, as illustrated in FIG. 5, or include the configuration of the output circuit 410 in FIG. 4 in other embodiments.

However, it is appreciated that since the delay amount of the output unit 110 in FIG. 5 is not variable, the signal output apparatus 100 may only include a part of the output units 110 having the configuration of FIG. 5 and is required to include the output units having the configuration in FIG. 2A, FIG. 2B or FIG. 4.

In some approaches, when each of the output units in a signal output apparatus has the same delay amount, the output units that are coupled in parallel and perform signal output simultaneously result in a smaller equivalent resistance such that the slew rate becomes higher. However, in some applications that operate the signal output apparatus under a lower frequency, the higher slew rate is not desirable. For example, for the High Definition Multimedia Interface operating in 3 Gbps, the rise time and the fall time of the signal are required to be above 75 picoseconds.

The signal output apparatus having the programmable slew rate in the present invention determines the slew rate of the total output signal according to different combinations of the different variable signal delay amounts of the output units to accomplish the elastic output mechanism with programmable slew rate. In practical applications, the combination of the variable signal delay amounts can be configured according to the different signal transmission interfaces and the amount of the frequency such that the slew rate matches the requirement.

It is appreciated that the embodiments described above are merely an example. In other embodiments, it is appreciated that many modifications and changes may be made by those of ordinary skill in the art without departing, from the spirit of the invention.

For example, the signal output apparatus 100 may include all the output units 110 having the configuration of FIG. 2A and FIG. 2B, include all the output units 110 having the configuration of FIG. 4, or include a part of the output units 110 having the configuration of FIG. 2A and FIG. 2B and include another part of the output units 110 having the configuration of FIG. 4. Further, the output circuit 410 in FIG. 4 may include the delay path 200 in FIG. 2A and FIG. 2B and the output circuit 210 may include the delay path 400 in FIG. 4. The present invention is not limited to a specific configuration.

In summary, the signal output apparatus having the programmable slew rate of the present invention disposes output units each corresponding to a variable signal delay amount so as to determine the slew rate of the total output signal according to the combination of the variable signal delay amounts of the different output units to accomplish a programmable slew rate that can be adjusted elastically.

The aforementioned descriptions represent merely the preferred embodiments of the present disclosure, without any intention to limit the scope of the present disclosure thereto. Various equivalent changes, alterations, or modifications based on the claims of present disclosure are all consequently viewed as being embraced by the scope of the present disclosure.

What is claimed is:

1. A signal output apparatus having programmable slew rate, comprising:
a plurality of output units electrically coupled in parallel between an input terminal and an output terminal each corresponding to a variable signal delay amount, each of the output units comprising:
a delay path configured to provide the variable signal delay amount and to receive and delay an input signal from the input terminal to generate a delayed signal; and
an output circuit to receive the delayed signal and generate an output signal to an output terminal;
wherein the output terminal outputs a total output signal according to the output signals generated from the output circuits of the output units, and a slew rate of the total output signal is determined by a combination of the variable signal delay amounts of all the output units.

2. The signal output apparatus of claim 1, wherein the output units are categorized into a plurality of output groups, the variable signal delay amount of each of the output units in the output groups is the same and the variable signal delay amounts of the output units in the different output groups are different.

3. The signal output apparatus of claim 2, wherein an equivalent RC time constant of the output units is a product of an equivalent resistance of the output units and a capacitance of a load capacitor at the output terminal, and the number of the output groups and the number of the output units in each of the output groups determine the equivalent RC time constant and further determine a linearity of the slew rate of the total output signal.

4. The signal output apparatus of claim 1, wherein the delay path comprises:
a multiplexer;
a first delay sub-path electrically coupled between the input terminal and the multiplexer and having a first delay element number of M to delay the input signal to generate a first delayed signal, wherein M is an integer larger than or equaling to 0; and
a second delay sub-path electrically coupled between the input terminal and the multiplexer and having a second delay element number of N that is different from the first delay element number of M to delay the input signal to generate a second delayed signal, wherein N is an integer larger than or equaling to 0;
the multiplexer is configured to select one of the first delayed signal and the second delayed signal to be outputted as the delayed signal.

5. The signal output apparatus of claim 4, further comprising a control circuit configured to generate a delay control signal to each of the output units to control the multiplexer to perform selection.

6. The signal output apparatus of claim 1, wherein the delay path of each of the output units comprises:
at least one delay element; and
at least one bypass element configured to bypass the delay element when being enabled and not bypass the delay element when being disabled.

7. The signal output apparatus of claim 6, further comprising a control circuit configured to generate a delay control signal to each of the output units to enable or disable the bypass element.

8. The signal output apparatus of claim 1, wherein the delay path of at least a part of the output units does not include any delay element.

9. The signal output apparatus of claim 1, wherein the output circuit is a flip-flop comprising:
a P-type transistor electrically coupled to a power supply terminal and a connection terminal, wherein the connection terminal is electrically coupled to the output terminal; and
an N-type transistor electrically coupled between the connection terminal and a ground terminal;
wherein the P-type transistor and the N-type transistor are controlled by the delayed signal and generate the output signal at the connection terminal.

10. The signal output apparatus of claim 9, wherein the flip-flop further comprises:
a first biased load transistor electrically coupled in series with the P-type transistor between the power supply terminal and the connection terminal; and
a second biased load transistor electrically coupled in series with the N-type transistor between the connection terminal and the ground terminal.
